(19) United States
(12) Patent Application Publication
(10) Pub. No.: US 2012/0244386 A1
(43) Pub. Date: Sep. 27, 2012

(54) COATED ARTICLE HAVING ANTIBACTERIAL EFFECT AND METHOD FOR MAKING THE SAME

(75) Inventors: HSIN-PEI CHANG, Tu-Cheng (TW); WEN-RONG CHEN, Tu-Cheng (TW); HUANN-WU CHIANG, Tu-Cheng (TW); CHENG-SHI CHEN, Tu-Cheng (TW); ZHI-JIE HU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD `, Shenzhen City (CN)

(21) Appl. No.: 13/210,752

(22) Filed: Aug. 16, 2011

(30) Foreign Application Priority Data
Mar. 25, 2011 (CN) 201110073091.8

(51) Int. Cl. B32B 15/01; C23C 14/34

(52) U.S. Cl. 428/660; 204/192.15

(57) ABSTRACT

A coated article is described. The coated article includes a substrate, an antibacterial layer formed on the substrate, and an anti-oxidation layer formed on the antibacterial layer. The antibacterial layer includes a plurality of alternating titanium films and copper films. A method for making the coated article is also described.

### CROSS-REFERENCE TO RELATED APPLICATIONS

This application is one of the four related co-pending U.S. patent applications listed below. All listed applications have the same assignee. The disclosure of each of the listed applications is incorporated by reference into the other listed applications.

BACKGROUND

| Attorney | | |
|---|---|---|
| Docket No. | Title | Inventors |
| US 37031 | COATED ARTICLE HAVING | HSIN-PEI |
| | ANTIBACTERIAL EFFECT AND METHOD | CHANG |
| | FOR MAKING THE SAME | et al. |
| US 39203 | COATED ARTICLE HAVING | HSIN-PEI |
| | ANTIBACTERIAL EFFECT AND METHOD | CHANG |
| | FOR MAKING THE SAME | et al. |
| US 39206 | COATED ARTICLE HAVING | HSIN-PEI |
| | ANTIBACTERIAL EFFECT AND METHOD | CHANG |
| | FOR MAKING THE SAME | et al. |
| US 40773 | COATED ARTICLE HAVING | HSIN-PEI |
| | ANTIBACTERIAL EFFECT AND METHOD | CHANG |
| | FOR MAKING THE SAME | et al. |

1. Technical Field

The present disclosure relates to coated articles, particularly to a coated article having an antibacterial effect and a method for making the coated article.

2. Description of Related Art

To make the living environment more hygienic and healthy, a variety of antibacterial products have been produced by coating substrates of the products with antibacterial metal films. The metal may be copper (Cu), zinc (Zn), or silver (Ag). However, the metal films are prone to oxidation. Moreover, the metal ions within the metal films rapidly dissolve from killing bacterium, so the metal films have a short lifespan.

Therefore, there is room for improvement within the art.

### BRIEF DESCRIPTION OF THE FIGURES

Many aspects of the disclosure can be better understood with reference to the following figures. The components in the figures are not necessarily drawn to scale, the emphasis instead being placed upon clearly illustrating the principles of the disclosure. Moreover, in the drawings like reference numerals designate corresponding parts throughout the several views.

FIG. 1 is a cross-sectional view of an exemplary embodiment of a coated article.

FIG. 2 is another cross-sectional view of an exemplary embodiment of a coated article.

FIG. 3 is an overhead view of an exemplary embodiment of a vacuum sputtering device.

### DETAILED DESCRIPTION

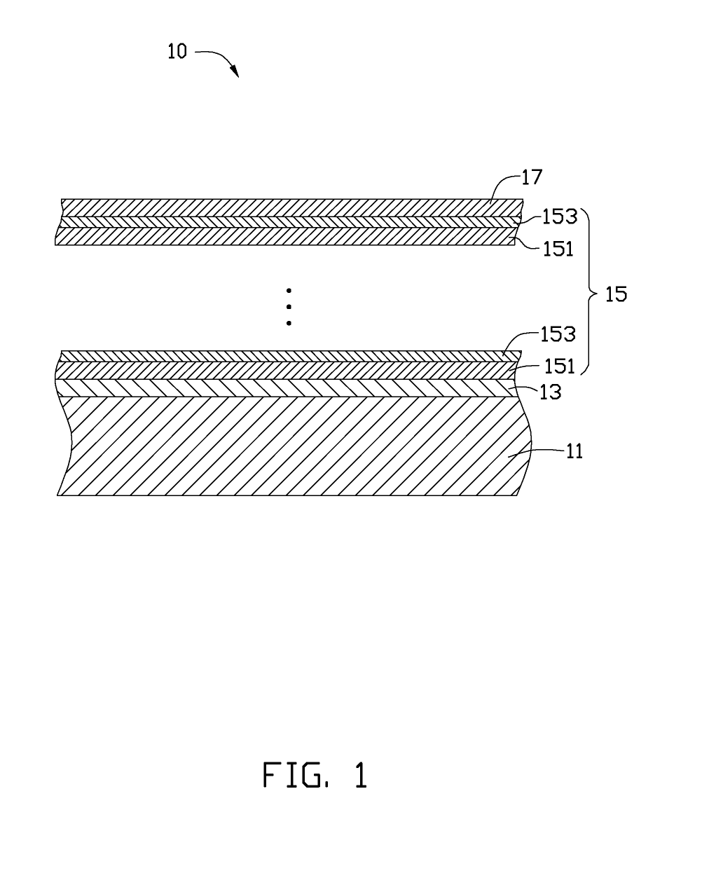

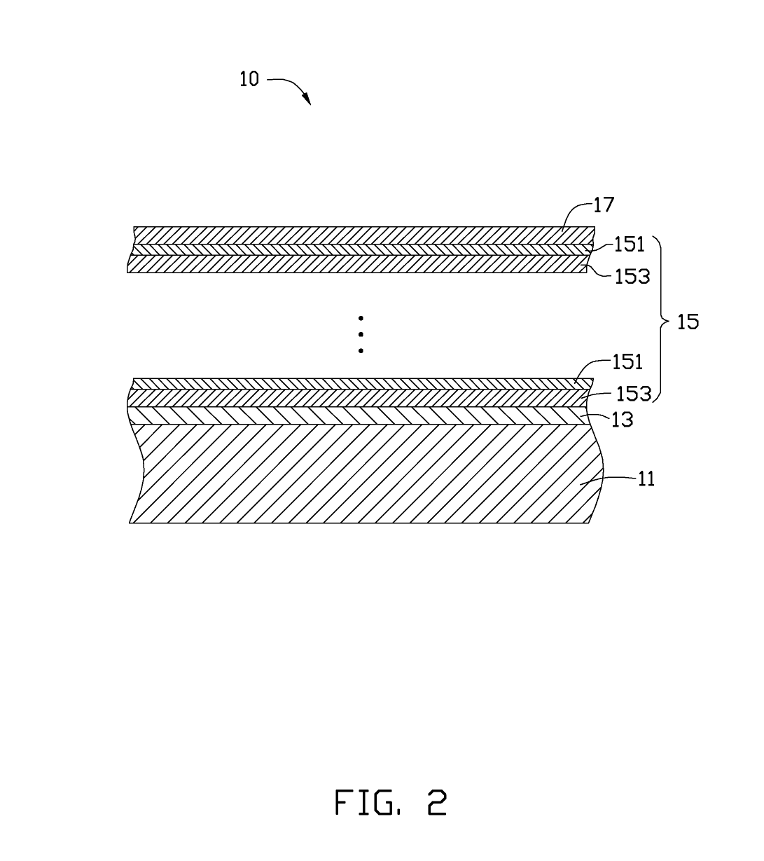

FIG. 1 and FIG. 2 show a coated article 10 according to an exemplary embodiment. The coated article 10 includes a substrate 11, a bonding layer 13 formed on the substrate 11, an antibacterial layer 15 formed on the bonding layer 13, and an anti-oxidation layer 17 formed on the antibacterial layer 15.

The substrate 11 may be made of stainless steel, but is not limited to stainless steel.

The bonding layer 13 may be a titanium (Ti) layer formed on the substrate 11 by vacuum sputtering. The bonding layer 13 has a thickness of about 50 nm-100 nm.

The antibacterial layer 15 may be formed by vacuum sputtering. The antibacterial layer 15 includes a plurality of copper (Cu) films 151 and a plurality of titanium (Ti) films 153. Each Cu film 151 alternates/interleaves with one Ti film 153. One of the Cu films 151 or one of the Ti films 153 is directly formed on the bonding layer 13. One of the Cu films 151 or one of the Ti films 153 is directly bonded with the anti-oxidation layer 17. The total thickness of the antibacterial layer 15 may be about 0.7 μm-1.5 μm. The Cu films 151 within the antibacterial layer 15 have an antibacterial property, the Ti films 153 within the antibacterial layer 15 inhibit the copper ions of the Cu films 151 from rapidly dissolving, so the antibacterial layer 15 has long-lasting antibacterial effect.

The anti-oxidation layer 17 may be formed by vacuum sputtering. The anti-oxidation layer 17 is a titanium (Ti) layer, which is inert and has anti-oxidation properties. Thus, the anti-oxidation layer 17 will prevent the antibacterial layer 15 from oxidation, which further prolongs the antibacterial effect of the coated article 10. The thickness of the anti-oxidation layer 17 may be about 20 nm-100 nm.

A method for making the coated article 10 may include the following steps:

The substrate 11 is pre-treated, such pre-treating process may include the following steps:

The substrate 11 is cleaned in an ultrasonic cleaning device (not shown) filled with ethanol or acetone.

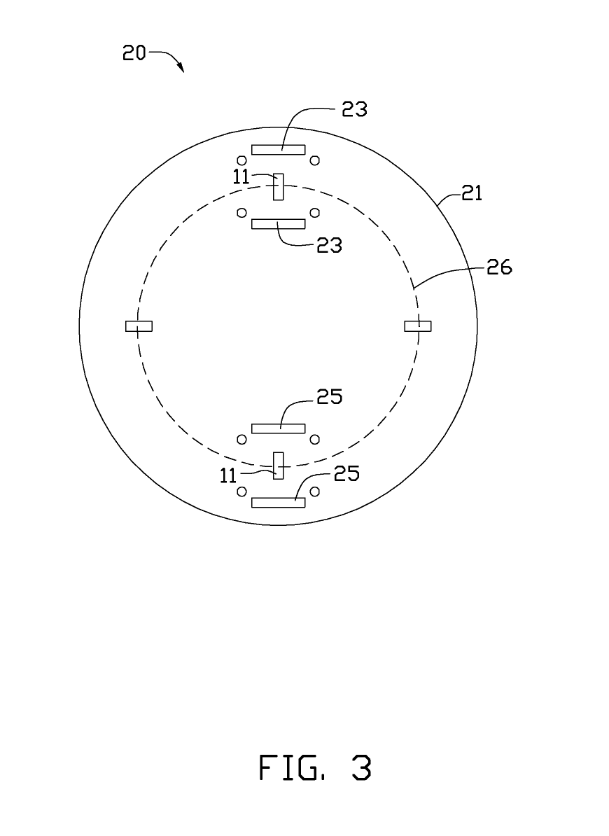

The substrate 11 is plasma cleaned. Referring to FIG. 3, the substrate 11 may be positioned in a coating chamber 21 of a vacuum sputtering device 20. The coating chamber 21 is fixed with titanium (Ti) targets 23 and copper (Cu) targets 25. The coating chamber 21 is evacuated to about 4.0×10⁻³ Pa. Argon gas (Ar) having a purity of about 99.999% may be used as a working gas and is fed into the coating chamber 21 at a flow rate of about 500 standard-state cubic centimeters per minute (sccm). The substrate 11 may have a bias voltage of about −200 V to about −350 V, then high-frequency voltage is produced in the coating chamber 21 and the argon gas is ionized to plasma. The plasma then strikes the surface of the substrate 11 to clean the surface of the substrate 11. Plasma cleaning of the substrate 11 may take about 3 minutes (min)-10 min. The plasma cleaning process enhances the bond between the substrate 11 and the bonding layer 13. The Ti targets 23 and the Cu targets 25 are unaffected by the pre-cleaning process.

The bonding layer 13 may be magnetron sputtered on the pretreated substrate 11. Magnetron sputtering of the bonding layer 13 is implemented in the coating chamber 21. The inside of the coating chamber 21 is heated to about 50° C.-250° C. Argon gas may be used as a working gas and is fed into the coating chamber 21 at a flow rate of about 100 sccm-300 sccm. Power of 5 kilowatt (KW) to about 10 KW is applied on the titanium targets 23, and titanium atoms are sputtered off from the titanium targets 23 to deposit on the substrate 11 and form the bonding layer 13. During the depositing process, the substrate 11 may have a bias voltage of about −50 V to about −250 V. Depositing of the bonding layer 13 may take about 5 min-10 min.

The antibacterial layer 15 may be magnetron sputtered on the bonding layer 13 using the titanium targets 23 and the copper targets 25 simultaneously. Magnetron sputtering of the antibacterial layer 15 is implemented in the coating chamber 21. The internal temperature of the coating chamber 21 is maintained at about 50° C.-250° C. Argon gas may be used as a working gas and is fed into the coating chamber 21 at a flow rate of about 100 sccm-300 sccm. A power of about 5 KW-10 KW is applied on the titanium targets 23, and another power of about 2 KW-8 KW is applied on the copper targets 25. Then titanium atoms and copper atoms are sputtered off from the titanium targets 23 and the copper targets 25 to alternatively deposit on the bonding layer 13 and form the antibacterial layer 15. During the depositing process, the substrate 11 is rotated along a locus 26 by using a rotating shelf (not shown) in which the substrate 11 is fixed. When the substrate 11 is rotated to the titanium targets 23, a Ti film 153 is deposited. When the substrate 11 is rotated to the copper targets 25, a Cu film 151 is deposited. As such, the antibacterial layer 15 including a plurality of alternating Cu films 151 and Ti films 153 is formed. During the depositing process, the substrate 11 may have a bias voltage of about −50 V to about −250 V. Depositing of the antibacterial layer 15 may take about 10 min-30 min.

The anti-oxidation layer 17 may be magnetron sputtered on the antibacterial layer 15 using the titanium targets 23. Magnetron sputtering of the anti-oxidation layer 17 is implemented in the coating chamber 21. The internal temperature of the coating chamber 21 is maintained at about 50° C.-250° C. Argon gas may be used as a working gas and is fed into the coating chamber 21 at a flow rate of about 100 sccm-300 sccm. Power of 5 KW-10 KW is applied on the titanium targets 23, and the Ti atoms are sputtered off from the titanium targets 23 to deposit on the antibacterial layer 15 and form the anti-oxidation layer 17 of Ti. During the depositing process, the substrate 11 may have a bias voltage of about −50 V to about −250 V. Depositing of the anti-oxidation layer 17 may take about 1 min-10 min.

Specific examples of making the coated article 10 are described as follows. The pre-treating process of ultrasonic and plasma cleaning the substrate 11 in these specific examples may be substantially the same as previously described so it is not described here again. Additionally, the magnetron sputtering processes of the bonding layer 13, antibacterial layer 15, and anti-oxidation layer 17 in the specific examples are substantially the same as described above, and the specific examples mainly emphasize the different process parameters of making the coated article 10.

### Example 1

The substrate 11 is made of stainless steel.

Sputtering to form the bonding layer 13 on the substrate 11: the flow rate of Ar is 150 sccm; the substrate 11 has a bias voltage of −50 V; the internal temperature of the coating chamber 21 is 120° C.; sputtering of the bonding layer 13 takes 10 min; the bonding layer 13 has a thickness of 100 nm.

Sputtering to form antibacterial layer 15 on the bonding layer 13: the flow rate of Ar is 150 sccm; the substrate 11 has a bias voltage of −50 V; the Ti targets 23 are applied with a power of 8 KW, the Cu targets 25 are applied with a power of 8 KW; the internal temperature of the coating chamber 21 is 120° C.; sputtering of the antibacterial layer 15 takes 15 min; the antibacterial layer 15 has a thickness of 900 nm.

Sputtering to form anti-oxidation layer 17 on the antibacterial layer 15: the flow rate of Ar is 150 sccm; the substrate 11 has a bias voltage of −50 V; the Ti targets 23 are applied with a power of 8 KW; the internal temperature of the coating chamber 21 is 120° C.; sputtering of the anti-oxidation layer 17 takes 5 min; the anti-oxidation layer 17 has a thickness of 50 nm.

### Example 2

The substrate 11 is made of stainless steel.

Sputtering to form the bonding layer 13 on the substrate 11: the flow rate of Ar is 150 sccm; the substrate 11 has a bias voltage of −100 V; the internal temperature of the coating chamber 21 is 120° C.; sputtering of the bonding layer 13 takes 5 min; the bonding layer 13 has a thickness of 70 nm.

Sputtering to form antibacterial layer 15 on the bonding layer 13: the flow rate of Ar is 150 sccm; the substrate 11 has a bias voltage of −100 V; the Ti targets 23 are applied with a power of 8 KW, the Cu targets 25 are applied with a power of 5 KW; the internal temperature of the coating chamber 21 is 120° C.; sputtering of the antibacterial layer 15 takes 20 min; the antibacterial layer 15 has a thickness of 950 nm.

Sputtering to form anti-oxidation layer 17 on the antibacterial layer 15: the flow rate of Ar is 150 sccm; the substrate 11 has a bias voltage of −100 V; the Ti targets 23 are applied with a power of 8 KW; the internal temperature of the coating chamber 21 is 120° C.; sputtering of the anti-oxidation layer 17 takes 5 min; the anti-oxidation layer 17 has a thickness of 50 nm.

An antibacterial performance test has been performed on the coated articles 10 described in the above examples 1-2. The test was carried out as follows:

Bacteria was firstly dropped on the coated article 10 and then covered by a sterilization film and put in a sterilization culture dish for about 24 hours at a temperature of about 37±1° C. and a relative humidity (RH) of more than 90%. Secondly, the coated article 10 was removed from the sterilization culture dish, and the surface of the coated article 10 and the sterilization film were rinsed using 20 milliliter (ml) wash liquor. The wash liquor was then collected in a nutrient agar to inoculate the bacteria for about 24 hours to 48 hours at about 37±1° C. After that, the number of surviving bacteria was counted to calculate the bactericidal effect of the coated article 10.

The test result indicated that the bactericidal effect of the coated article 10 with regard to escherichia coli, salmonella, and staphylococcus aureus was no less than 99.99%.

An anti-oxidation performance test has also been performed on the coated articles 10 described in the above examples 1-2. The test result indicated that, after accelerated oxidation for about 60 hours at a temperature of about 150° C. and at a relative humidity (RH) of about 100%, the coated articles 10 were not oxidized.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

1. A coated article, comprising:
a substrate;
an antibacterial layer formed on the substrate, the antibacterial layer comprising a plurality of alternating copper films and titanium films; and
an anti-oxidation layer formed on the antibacterial layer.

2. The coated article as claimed in claim 1, wherein the antibacterial layer has a total thickness of about 0.7 μm-1.5 μm.

3. The coated article as claimed in claim 1, wherein the anti-oxidation layer is a titanium layer and has a thickness of about 20 nm-100 nm.

4. The coated article as claimed in claim 1, further comprising a bonding layer formed between the substrate and the antibacterial layer.

5. The coated article as claimed in claim 4, wherein the bonding layer is a titanium layer and has a thickness of about 50 nm-100 nm.

6. The coated article as claimed in claim 4, wherein one of the titanium films or one of the copper films is directly formed on the bonding layer; one of the titanium films or one of the copper films is directly bonded with the anti-oxidation layer.

7. The coated article as claimed in claim 1, wherein the substrate is made of stainless steel.

8. A method for making a coated article, comprising:
providing a substrate;
forming an antibacterial layer on the substrate by vacuum sputtering, using a titanium target and a copper target; the antibacterial layer comprising a plurality of alternating copper films and titanium films; and
forming an anti-oxidation layer on the antibacterial layer by vacuum sputtering.

9. The method as claimed in claim 8, wherein forming the antibacterial layer uses a magnetron sputtering method; the titanium target is applied with a power of about 5 KW-10 KW, the copper target is applied with a power of about 2 KW-8 KW; magnetron sputtering of the antibacterial layer uses argon as a working gas, the argon has a flow rate of about 100 sccm-300 sccm; magnetron sputtering of the antibacterial layer is conducted at a temperature of about 50° C.-250° C. and takes about 10 min-30 min.

10. The method as claimed in claim 9, wherein the substrate has a bias voltage of about −50V to about −250V during magnetron sputtering of the antibacterial layer.

11. The method as claimed in claim 8, wherein forming the anti-oxidation layer uses a magnetron sputtering method, uses a titanium target, the titanium target is applied with a power of about 5 KW-10 KW; magnetron sputtering of the anti-oxidation layer uses argon as a working gas, the argon has a flow rate of about 100 sccm-300 sccm; magnetron sputtering of the anti-oxidation layer is conducted at a temperature of about 50° C.-250° C. and takes about 1 min-7 min.

12. The method as claimed in claim 11, wherein the substrate has a bias voltage of about −50V to about −250V during magnetron sputtering of the anti-oxidation layer.

13. The method as claimed in claim 8, further comprising a step of forming a bonding layer on the substrate before forming the antibacterial layer.

14. The method as claimed in claim 13, wherein forming the bonding layer uses a magnetron sputtering method, uses titanium target, the titanium target is applied with a power of about 5 KW-10 KW; uses argon as a working gas, the argon has a flow rate of about 100 sccm-300 sccm; magnetron sputtering of the bonding layer is conducted at a temperature of about 50° C.-250° C. and takes about 5 min-10 min.

15. The method as claimed in claim 14, wherein the substrate has a bias voltage of about −50V to about −250V during magnetron sputtering of the bonding layer.

16. The method as claimed in claim 13, further comprising a step of pre-treating the substrate before forming the bonding layer.

17. The method as claimed in claim 16, the pre-treating process comprises ultrasonic cleaning the substrate and plasma cleaning the substrate.
